(19) United States
(12) Patent Application Publication
(10) Pub. No.: US 2026/0074156 A1
(43) Pub. Date: Mar. 12, 2026

(54) VACUUM-INSULATED, HEATED REACTOR CONSTRUCTION

(71) Applicant: LAM RESEARCH CORPORATION, Fremont, CA (US)

(72) Inventors: Karl Frederick LEESER, West Linn, OR (US); Emile Charles DRAPER, Molalla, OR (US); Yi-De WU, Beaverton, OR (US); Gaosheng FU, Beaverton, OR (US)

(21) Appl. No.: 18/870,179

(22) PCT Filed: May 19, 2023
(86) PCT No.: PCT/US2023/022926

§ 371 Date: Nov. 27, 2024

Related U.S. Application Data
(60) Provisional application No. 63/349,967, filed on Jun. 7, 2022.

(51) Int. Cl. H01J 37/32; H01L 21/67

(52) U.S. Cl. CPC H01J 37/32467; H01J 37/32183; H01J 37/32724; H10P 72/0432

(57) ABSTRACT

A sidewall assembly of a substrate processing chamber has a composite structure comprising an inner layer comprised of a first material and an inward, chamber facing surface, an outer layer that is comprised of a second material and encloses the inner layer, and a middle layer disposed around the inner layer between the inner layer and the outer layer that thermally insulates the outer layer from the inner layer.

### CROSS-REFERENCE TO RELATED APPLICATIONS

This application claims the benefit of U.S. Provisional Application No. 63/349,967 filed on Jun. 7, 2022. The entire disclosure of the above application is incorporated herein by reference.

### FIELD

The present disclosure relates to substrate processing systems, and more particularly to construction of chamber walls of a substrate processing chamber or reactor.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate processing system typically comprises a plurality of processing chambers (also called process modules) to perform deposition, etching, and other treatments of substrates such as semiconductor wafers. Examples of processes that may be performed on a substrate comprise chemical vapor deposition (CVD), plasma enhanced CVD (PECVD), chemically enhanced plasma vapor deposition (CEPVD), atomic layer deposition (ALD), and plasma enhanced ALD (PEALD). Additional examples of processes that may be performed on a substrate comprise etching (e.g., chemical etching, plasma etching, reactive ion etching, etc.) and cleaning processes.

During processing, a substrate is arranged on a substrate support or a susceptor such as a pedestal, an electrostatic chuck (ESC), and so on in a processing chamber of the substrate processing system. In some processes, during deposition, gas mixtures comprising one or more precursors are introduced into the processing chamber, and plasma may be struck to activate chemical reactions. In other processes, during etching, gas mixtures comprising etch gases are introduced into the processing chamber, and plasma may be struck to activate chemical reactions. A computer-controlled robot is used to transfer substrates from one processing chamber to another in a sequence in which the substrates are to be processed.

Some processes are performed in a heated processing chamber. For example, the substrate support, an upper electrode or showerhead, and/or other components of the processing chamber may be actively heated.

### SUMMARY

A sidewall assembly of a substrate processing chamber has a composite structure comprising an inner layer comprised of a first material and an inward, chamber facing surface, an outer layer that is comprised of a second material and encloses the inner layer, and a middle layer disposed around the inner layer between the inner layer and the outer layer that thermally insulates the outer layer from the inner layer.

In other features, the inner layer is comprised of a first material with a first thermal conductivity, the inward, chamber facing surface absorbs and distributes heat generated within the substrate processing chamber, the outer layer is comprised of a second material with a second thermal conductivity less than the first thermal conductivity, and the middle layer is comprised of a third material with a third thermal conductivity less than the first thermal conductivity to thermally insulate the outer layer from the inner layer.

In other features, the inner layer is comprised of aluminum. The outer layer is comprised of aluminum. The outer layer is comprised of a polymer. The middle layer is comprised of a discontinuous heat capture structure. The discontinuous heat capture structure defines a plurality of interconnected cells within the middle layer. The heat capture structure is comprised of one of a honeycomb structure, structurally expanded metal, a lattice structure, or a perforated structure. The heat capture structure is a honeycomb structure comprised of one or more of a synthetic polymer or copolymer. The honeycomb structure is comprised of one or more of aramid, cellulose fiber, rayon, and modacrylic.

In other features, a vacuum is formed within the plurality of interconnected cells of the middle layer. At least one of an inward-facing surface of the outer layer and an outward-facing surface of the inner layer comprises un ultra-reflective infrared coating. The coating is a barium sulfate coating. The sidewall assembly further comprises an adhesive film disposed between the inner layer and the middle layer, between the middle layer and the outer layer, or between the inner layer and the middle layer and between the middle layer and the outer layer. The sidewall assembly further comprises at least one of a bottom wall and a top wall of the substrate processing chamber.

A processing chamber for a substrate processing system has a composite structure comprising a sidewall assembly enclosing a reactor volume and a pedestal disposed within the reactor volume, the pedestal comprising heating elements to heat a substrate supported on the pedestal. The sidewall assembly comprises an inner layer with an inward, reactor volume facing surface to absorb and distribute heat generated within the reactor volume, an outer layer that encloses the inner layer to define a gap between the inner layer and the outer layer, and a middle layer disposed around the inner layer in the gap defined between the inner layer and the outer layer. The middle layer is comprised of a discontinuous heat capture structure to thermally insulate the outer layer from the inner layer.

In other features, the inner layer is comprised of aluminum, the outer layer is comprised of one of a polymer and aluminum, and the middle layer is comprised of a honeycomb structure that defines a plurality of interconnected cells within the middle layer. The honeycomb structure is comprised of one or more of aramid, cellulose fiber, rayon, and modacrylic. The honeycomb structure is comprised of expanded metal. A vacuum is formed within the gap.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 shows an example of a substrate processing system according to the present disclosure;

FIG. 2A shows a cross-sectional side view of an example processing chamber according to the present disclosure;

FIG. 2B shows a top down (plan) view of an example processing chamber according to the present disclosure;

FIG. 2C shows a cross-sectional side view of another example processing chamber according to the present disclosure;

FIG. 2D shows the cross-sectional view of the example processing chamber of FIG. 2A in more detail;

FIG. 3 shows an example construction of a sidewall of a processing chamber according to the present disclosure; and

FIG. 4 illustrates steps of an example method of assembling a processing chamber according to the present disclosure.

In the drawings, reference numbers may be reused to identify similar and/or identical elements.

### DETAILED DESCRIPTION

Typically, resistively heated pedestals or susceptors are used for heating substrates during semiconductor substrate processes, such as in deposition applications. A pedestal comprises a thermally conductive body, usually fabricated from a metal such as aluminum, that monolithically houses a heater element that heats the thermally conductive body. The thermally conductive body spreads out heat flux to heat a substrate arranged on the pedestal during processing. Gas conduction combined with radiation between the substrate and the heated pedestal thermally couples the substrate to the pedestal. Other components (e.g., upper electrodes or showerheads) may also be heated to improve process uniformity.

Processing chambers (e.g., reactors) are typically fabricated from aluminum plate stock and/or stainless steel. In one example, processing chambers are fabricated from aluminum plate stock using subtractive machining. In another example, processing chambers are fabricated by welding plates or cylindrical shells of stainless steel or aluminum to form sidewalls of the processing chambers. Fabrication of processing chambers in this manner enables a high degree of geometrical control of precision reactor features and relatively high temperature uniformity. However, the materials used in these processing chambers absorb a large amount of heat from the systems used to heat the substrates. For example, while resistive heating technology may be 100% efficient in converting electrical to thermal energy, only 25% of the converted thermal energy is actually used to heat the substrate support, showerhead, and substrate while the remaining 75% is lost through absorption by other components (e.g., sidewalls of the processing chamber).

A processing chamber according to the present disclosure comprises composite, insulated (e.g., vacuum-insulated) sidewalls. The sidewalls are comprised of an inner, chamber-facing layer (e.g., having a chamber-facing surface facing an inner volume of the processing chamber), an outer layer, and a vacuum-insulated middle layer defined between the inner layer and the outer layer. For example, the inner layer is comprised of high purity aluminum to provide precision geometric features, high thermal absorption to facilitate temperature uniformity, and minimal particle generation and interference with process chemistry. The outer layer is comprised of a polymer or low-cost (i.e., relative to the inner layer) aluminum. The outer layer is an environment-facing layer that is not exposed to the interior of the processing chamber. In some examples, an outward-facing surface of the inner layer and/or an inward-facing surface of the outer layer may have an ultra-reflective infrared coating, such as a barium sulfate coating.

The middle layer may comprise a honeycomb or other discontinuous structure, such as a structurally expanded metal (e.g., aluminum), lattice, or perforated structure. As one example, the middle layer is comprised of a honeycomb or perforated tape. Accordingly, the middle layer defines a plurality of interconnected cells (i.e., volumes or voids) in a gap between the inner layer and the outer layer. The gap may be pumped down or evacuated to form a vacuum between the inner layer and the outer layer. The vacuum may be formed during manufacture. In other examples, the gap may be pumped down to vacuum by the substrate processing system.

In this manner, the middle layer captures radiative heat emitted from the inner layer while the vacuum defined in the gap provides thermal insulation between the inner layer and the outer layer.

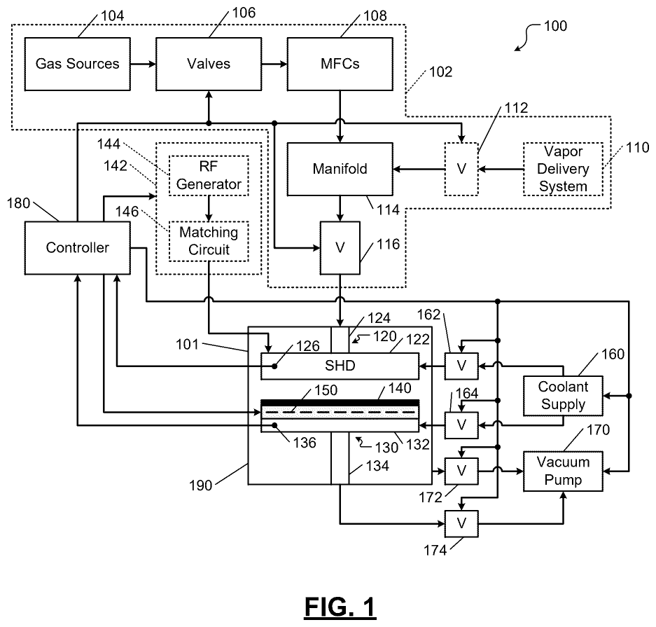

FIG. 1 shows an example of a substrate processing system (hereinafter the system 100). The system 100 as shown can be used to process substrates using chemical vapor deposition (CVD), plasma enhanced CVD (PECVD), chemically enhanced plasma vapor deposition (CEPVD), atomic layer deposition (ALD), or plasma enhanced ALD (PEALD) processes. In other example, the system 100 may be used to perform etching process, both deposition and etching processes, etc.

The system 100 comprises a processing chamber (e.g., a reactor) 101 and a gas distribution system 102. The gas distribution system 102 comprises a plurality of gas sources 104, a plurality of valves 106 connected to the gas sources 104, and a plurality of mass flow controllers (MFCs) 108 connected to the valves 106. The gas sources 104 supply various gases comprising process gases, precursors, purge gases, inert gases, cleaning gases, etc. The MFCs 108 control the mass flow rates of the gases.

In some applications, the gas distribution system 102 further comprises a vapor delivery system 110 to supply one or more vaporized precursors through one or more valves 112. One or more gases from the MFCs 108 and, when used, one or more vaporized precursors are supplied to a mixing manifold 114. The gases or gas mixtures from the mixing manifold 114 are supplied to the processing chamber 101 through a valve assembly (e.g., a pulsed valve manifold or PVM assembly) 116.

The processing chamber 101 comprises a showerhead 120 and a substrate support, such as a pedestal 130. The showerhead 120 is attached to a top plate of the processing chamber 101. The showerhead 120 receives the gases or gas mixtures from the mixing manifold 114 through the valve assembly 116. The showerhead 120 comprises a base portion 122 and a stem portion 124. The stem portion 124 extends from the center of the base portion 122 and is attached to the top plate of the processing chamber 101. The base portion 122 is cylindrical and comprises a plurality of through holes (not shown) through which the gases or gas mixtures are supplied into the processing chamber 101.

The pedestal 130 comprises a base portion 132 and a stem portion 134. The stem portion 134 is generally cylindrical or can be Y-shaped, with the tapered (i.e., the top of the Y) portion attached to a bottom of the base portion 132. The stem portion 134 extends from the base portion 132 and is attached to the bottom of the processing chamber 101. The base portion 132 is also cylindrical. A substrate 140 is arranged on a top surface of the base portion 132 of the pedestal 130 during processing. The base portion 132 comprises heating elements (e.g., an array of resistive heating elements) 150 to heat the substrate 140. In some examples, the showerhead 120 is heated (e.g., using one or more resistive heating elements).

While not shown, the base portion 132 of the pedestal 130 may comprise lift pins to hold, lower, and raise the substrate 140 relative to the base portion 132 of the pedestal 130. Optionally, a shaft (shown and described below) extending through the stem portion 132 and the base portion 132 of the pedestal 130 may be used to hold, lower, and raise the substrate 140 relative to the base portion 132 of the pedestal 130. The lift pins and the shaft can be used in combination to hold, lower, and raise the substrate 140 relative to the base portion 132 of the pedestal 130.

In some applications, plasma may be used to process the substrate 140. The system 100 comprises a radio frequency (RF) system 142 used to generate plasma in the processing chamber 101. The RF system 142 comprises a RF generator 144 and a matching circuit 146. The RF system 142 supplies RF power to the showerhead 120 while the pedestal 130 is grounded. Alternatively, while not shown, the RF power can be supplied to the pedestal 130 while the showerhead 120 is grounded. The RF power activates the gases or gas mixtures supplied through the showerhead 120 and generates plasma between the showerhead 120 and the substrate 140 arranged on the pedestal 130.

The showerhead 120 and the pedestal 130 comprise temperature sensors 126, 136 to sense the temperatures of the showerhead 120 and the pedestal 130. The showerhead 120 and the pedestal 130 may comprise cooling channels (not shown). A coolant is circulated through the cooling channels to control the temperatures of the showerhead 120 and the pedestal 130. A coolant supply 160 may supply the coolant to the cooling channels in the showerhead 120 and the pedestal 130 via valves 162, 164.

A vacuum pump 170 is connected to the bottom of the processing chamber 101 through a valve 172. The vacuum pump 170 is used to maintain vacuum in the processing chamber 101 and to evacuate reactants and process byproducts from the processing chamber 101. Additionally, when vacuum clamping is used, the vacuum pump 170 is connected to the stem portion 134 of the pedestal 130 through a valve 174. The vacuum pump 170 maintains vacuum through an annular volume around the shaft in the stem portion 134 of the pedestal 130 (shown and described below) to clamp the substrate 140 to the pedestal 130.

A controller 180 controls the various elements of the system 100 (e.g., the gas distribution system 102, the valves, the RF system 142, the heating elements 150, the coolant supply 160, the vacuum pump 170, etc.). The controller 180 receives data from the temperature sensors 126, 136 and controls the temperatures of the showerhead 120 and the pedestal 130 by controlling the heating elements 150 and the coolant supply 160.

The processing chamber 101 according to the present disclosure comprises composite (e.g., composite, vacuum-insulated) sidewalls 190. As described below in more detail, the sidewalls 190 are comprised of an inner, chamber-facing layer, an outer layer, and a vacuum-insulated (i.e., thermally resistive) middle layer defined between the inner layer and the outer layer. The middle layer is constructed to provide both thermal insulation to minimize heat transfer from the inner layer to the outer layer and capture of radiative heat emitted from the inner layer. In some examples, the middle layer comprises a discontinuous (e.g., honeycomb, structurally expanded, lattice, perforated, etc.) heat capture structure that captures radiant heat. Accordingly, the middle layer comprises a plurality of interconnected cells (e.g., defined within the heat capture structure) that can be pumped down to vacuum to provide thermal insulation. The middle layer provides a combination of structural rigidity between the inner layer and the outer layer, low thermal conductivity from the inner layer to the outer layer, and minimal heat loss caused by convective, conducive, and radiant heat transfer.

Although described with respect to the sidewalls 190, a bottom wall or surface, upper wall or surface (e.g., lid), and/or other structures of the processing chamber 101 may also be comprised of the vacuum-insulated sidewalls described below.

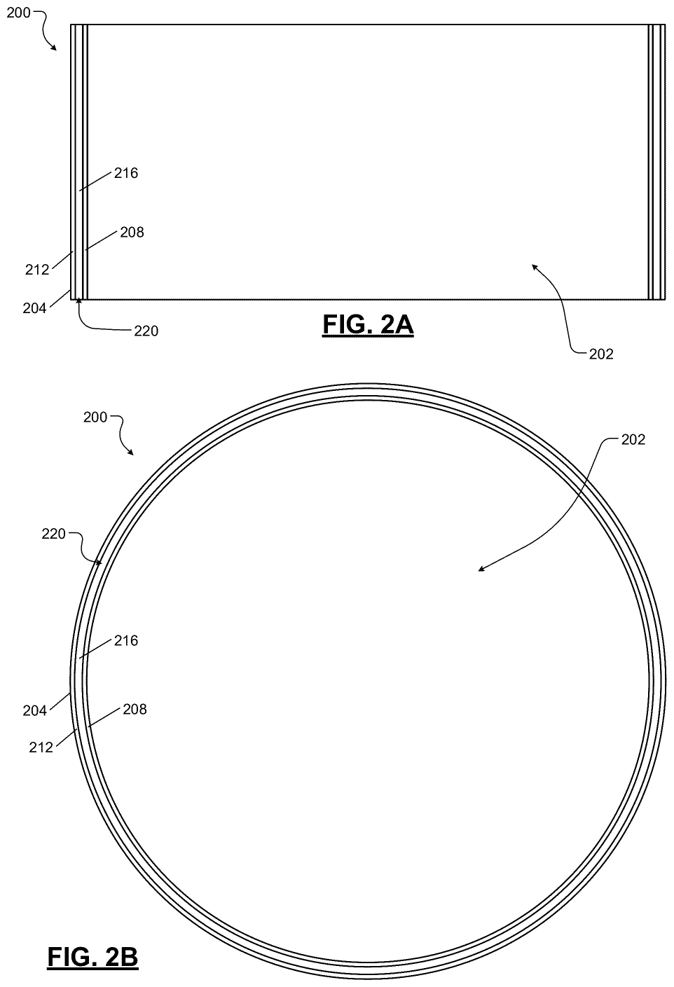

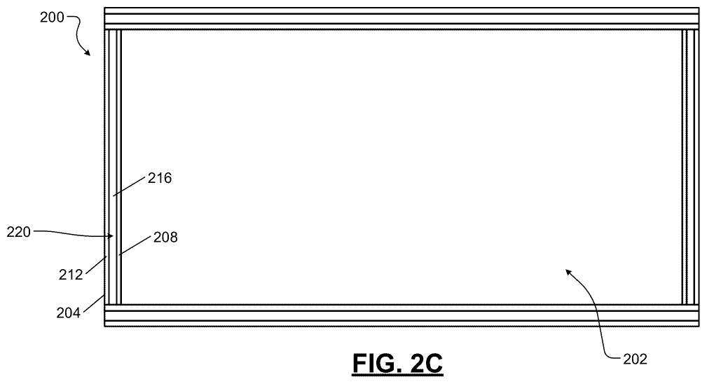

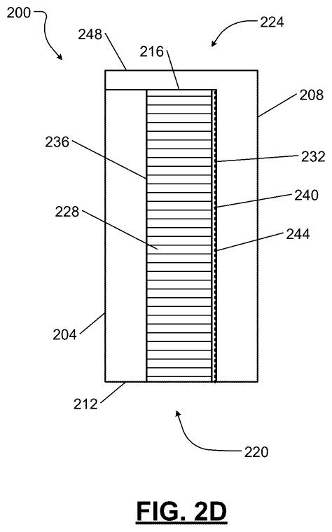

An example processing chamber (e.g., a sidewall assembly for a substrate processing chamber comprising composite sidewalls) 200 according to the present disclosure is shown in a cross-sectional side view in FIG. 2A and a top-down (plan) view in FIG. 2B. Although shown as being generally cylindrical, the processing chamber 200 may have other shapes. The processing chamber 200 encloses a processing (e.g., reactor) volume 202.

A sidewall assembly comprising sidewalls 204 of the processing chamber 200 have a composite, thermally insulated construction as discussed above and as described below in more detail. The sidewalls 204 are comprised of an inner layer 208, an outer layer 212, and a thermally insulative middle layer 216 defined between the inner layer 208 and the outer layer 212. The inner layer 208 is comprised of two sides or surfaces. A first surface of the inner layer 208 is a chamber-facing surface (i.e., a surface facing an inner volume of the processing chamber 200). A second surface opposite the first surface faces the middle layer 216.

For example, the inner layer 208 is comprised of aluminum, a wrought aluminum alloy, stainless steel or stainless-steel alloys, nickel-chromium alloys, etc. The outer layer 212 may be comprised of a metal (e.g., steel alloy, stainless steel, aluminum or aluminum alloy, etc.) or a polymer. The inner layer 208 has a greater thermal conductivity than the middle layer 216 and the outer layer 212. For example, the inner layer 208 is comprised of a material having a first thermal conductivity, the middle layer 216 is comprised of a material having a second thermal conductivity less than the first thermal conductivity, and the middle layer 216 is comprised of a third material having a third thermal conductivity less than the first thermal conductivity. In some examples, the third thermal conductivity is less than the second thermal conductivity.

Further, although shown in FIG. 2A as not comprising a bottom wall or surface or a top wall or surface (e.g., a lid), the processing chamber 200 according to the present disclosure may also comprise top and/or bottom walls constructed in the same or similar manner as the sidewalls (i.e., with the same composite structure as the sidewalls). For example, FIG. 2C shows an example of the processing chamber 200 (e.g., a sidewall assembly) comprising a top surface and a bottom surface each with a composite, thermally insulated construction comprised of the inner layer 208, the outer layer 212, and the middle layer 216.

Relative thicknesses of the inner layer 208, the outer layer 212, and the middle layer 216 may vary based on application, overall size of the processing chamber 200, etc. For example only, each of the layers may have a thickness in a range from 1.0 to 100 mm. In an example, the inner layer 208 is thinner than the outer layer 212 and the middle layer 216.

The middle layer 216 is disposed within a gap 220 defined between the inner layer 208 and the outer layer 212. In one example, the middle layer 216 is comprised of a discontinuous heat capture structure that defines a plurality of interconnected cells. For example, the heat capture structure is a honeycomb structure and the gap 220 is evacuated (e.g., pumped down) during manufacture/assembly such that a vacuum is formed between the inner layer 208 and the outer layer 212. In other words, the vacuum is formed in the cells defined within the honeycomb structure. In other examples, the middle layer 216 is comprised of a continuous insulative layer, a gap that is pumped down to vacuum without a honeycomb or any other structure, etc.

FIG. 2D shows a closeup view of the construction of the sidewall 204. For example, the inner layer 208, the outer layer 212, and the middle layer 216 are shown at an upper end 224 of the sidewall 204. As shown, the middle layer 216 is a discontinuous heat capture structure. More specifically, the middle layer 216 is a honeycomb structure that defines a plurality of interconnected cells 228. The honeycomb structure may be comprised of metal or one or more polymers and/or combinations of polymers, such as aramid, cellulose fiber, rayon, modacrylic, and/or other synthetic polymers or copolymers. In an example, the honeycomb structure is comprised of structurally expanded metal, such as structurally expanded aluminum, steel or steel alloy, etc. In another example, the honeycomb structure is comprised of a ceramic material (aluminum oxide, quartz, etc.).

In some examples, an outward-facing surface 232 of the inner layer 208 and/or an inward-facing surface 236 of the outer layer 212 may have an ultra-reflective infrared coating 240, such as a barium sulfate coating. As shown, the outward-facing surface 232 of the inner layer 208 comprises the coating 240 to reflect heat from the inner layer 208 back toward an interior of the processing chamber 200. Accordingly, the coating 240 further reduces heat transfer from the inner layer 208 to the middle layer 216.

In some examples, the middle layer 216 is attached to the inner layer 208 using an adhesive tape or film 244. For example, the adhesive film 244 is comprised of a high temperature polymer. The adhesive film 244 is disposed on the outward-facing surface 232 of the inner layer 208. The middle layer 216 is disposed on the adhesive film 244 to adhere the middle layer 216 to the inner layer 208. Although not shown, the adhesive film 244 may also be used to adhere the outer layer 212 to the middle layer 216. For example, the adhesive film 244 is disposed between the middle layer 216 and the outer layer 212.

As shown, an upper end of the inner layer 208 comprises an annular rim, flange, or lip 248 that extends radially outward toward the outer layer 212 (i.e., at the upper end 224 of the sidewall 204). In other words, the rim 248 overlaps the outer layer 212. Conversely, a similar rim may extend radially outward from a lower end of the inner layer 208. In this manner, an assembly comprising the inner layer 208 and the outer layer 212 defines the gap 220 and encloses the middle layer 216 within the gap 220. In other examples, the outer layer 212 may comprise a rim that extends radially inward. In still other examples, both the inner layer 208 and the outer layer 212 comprise complementary rims that extend toward each other above and below the middle layer 216. Other suitable configurations may be used.

In this manner, the inner layer 208 and the outer layer 212 seal the gap 220 from atmosphere. For example, a vacuum is formed in the gap 220 during manufacture/assembly of the processing chamber 200. The inner layer 208 and the outer layer 212 are fixedly attached together to retain the vacuum within the gap 220. In one example, the inner layer 208 and the outer layer 212 are welded or brazed together. In another example, the outer layer 212 is attached to the inner layer 208 using a thermally insulative adhesive (e.g., a thermal epoxy).

In other examples, the gap 220 may be pumped down to vacuum during processing. For example, the gap 220 may have a port or valve (not shown) in selective fluid communication with the vacuum pump 170. In this manner, the gap 220 may be periodically (e.g., prior to performing a process or process step) pumped down to vacuum.

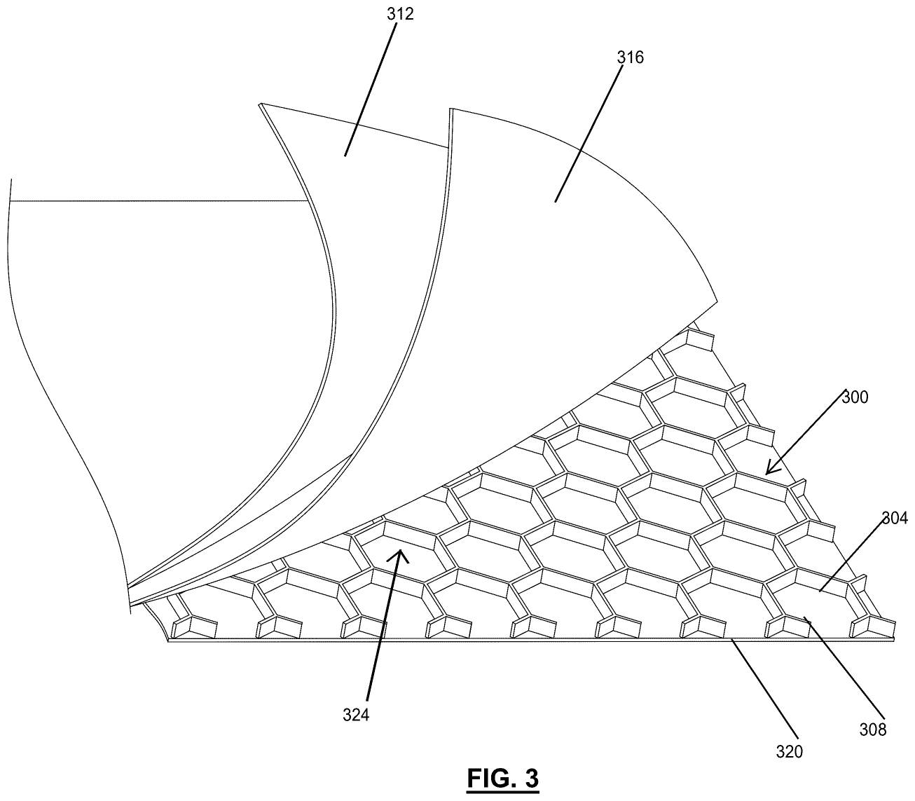

FIG. 3 shows an example middle layer 300 of one of the sidewalls 204. In this example, the middle layer 300 is comprised of a honeycomb structure 304. In other words, the middle layer 300 is comprised of a discontinuous heat capture structure that defines a plurality of interconnected cells 308. The middle layer 300 is coupled to an inner layer 312 using an adhesive film 316. An outer layer 320 is disposed on the middle layer 300. The middle layer 300 is thereby enclosed within a vacuum-sealed gap 324 defined between the inner layer 312 and the outer layer 320.

Accordingly, the honeycomb structure 304 provides structural rigidity to the sidewall 204 and, more specifically, to the inner layer 312. For example, the honeycomb structure 304 is directly or indirectly (i.e., via the film 316) in contact with the inner layer 312 and the outer layer 320. The honeycomb structure 304 is comprised of a material selected to absorb radiant heat emitted from the inner layer 312, such as aluminum. Further, the voids defined within the interconnected cells 308 provide additional reduction of heat transfer from the inner layer 312 to the outer layer 320. In examples where a vacuum is formed within the gap 324 (and the cells 308), heat transfer is even further reduced.

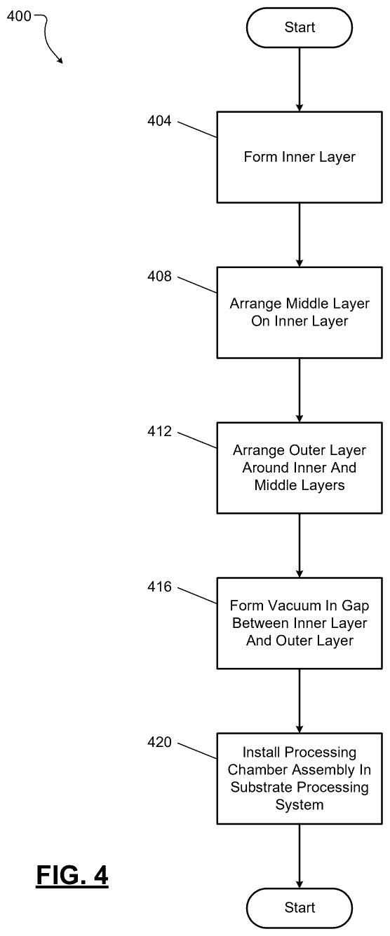

FIG. 4 illustrates steps of an example method 400 of assembling a processing chamber assembly according to the present disclosure. At 404, an inner, chamber-facing layer (e.g., the inner layer 208) is formed. As one example, the inner layer is stamped from a sheet of aluminum and subsequently reshaped (e.g., rolled) into a cylinder and ends of the sheet are welded together. In another example, the inner layer is formed using a thin-wall aluminum die casting process.

At 408, a middle layer (e.g., the middle layer 216) is arranged on the inner layer. For example, the middle layer is a honeycomb tape that is wrapped around and adhered to the inner layer. In one example, the middle layer is adhered to the inner layer using an adhesive tape.

At 412, an outer layer is arranged around the inner and middle layers. In one example, the outer layer is comprised of aluminum that is formed using a same process as the inner layer (e.g., a die casting or other process). In another example, the outer layer is comprised of a polymer. The outer layer may be comprised of a single piece or multiple pieces fused (e.g., welded) together around the inner layer and the middle layer.

At 416, a vacuum optionally is formed within the processing chamber assembly. For example, a vacuum is formed in a gap defined between the inner layer and the outer layer. In one example, the gap is pumped down to vacuum through a one-way port, an opening or seam between the inner layer and outer layer that is subsequently sealed, etc. In another example, the gap is pumped down to vacuum during processing (e.g., using the vacuum pump 170). At 420, the processing chamber assembly is installed in a substrate processing system.

The method 400 described above in FIG. 4, is only one example method of assembling a processing chamber according to the principles of the present disclosure and other methods may be used. For example, the entire composite structure may be fabricated using an additive manufacturing method. In another example, respective layers of the processing chamber may be coupled together using mechanical fasteners, welds, clamps, etc. In still another example, the layers may be coupled together using a press fit or shrink fit method.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A sidewall assembly of a substrate processing chamber, the sidewall assembly having a composite structure comprising:
an inner layer comprised of a first material, wherein the inner layer comprises an inward, chamber facing surface;
an outer layer comprised of a second material, wherein the outer layer encloses the inner layer; and
a middle layer disposed around the inner layer between the inner layer and the outer layer, wherein the middle layer thermally insulates the outer layer from the inner layer.

2. The sidewall assembly of claim 1, wherein:
the inner layer is comprised of a first material with a first thermal conductivity, wherein the inward, chamber facing surface absorbs and distributes heat generated within the substrate processing chamber;
the outer layer is comprised of a second material with a second thermal conductivity less than the first thermal conductivity; and
the middle layer is comprised of a third material with a third thermal conductivity less than the first thermal conductivity to thermally insulate the outer layer from the inner layer.

3. The sidewall assembly of claim 2, wherein the inner layer is comprised of aluminum.

4. The sidewall assembly of claim 3, wherein the outer layer is comprised of aluminum.

5. The sidewall assembly of claim 3, wherein the outer layer is comprised of a polymer.

6. The sidewall assembly of claim 1, wherein the middle layer is comprised of a discontinuous heat capture structure.

7. The sidewall assembly of claim 6, wherein the discontinuous heat capture structure defines a plurality of interconnected cells within the middle layer.

8. The sidewall assembly of claim 7, wherein the heat capture structure is comprised of one of a honeycomb structure, structurally expanded metal, a lattice structure, or a perforated structure.

9. The sidewall assembly of claim 7, wherein the heat capture structure is a honeycomb structure comprised of one or more of a synthetic polymer or copolymer.

10. The sidewall assembly of claim 9, wherein the honeycomb structure is comprised of one or more of aramid, cellulose fiber, rayon, and modacrylic.

11. The sidewall assembly of claim 7, wherein a vacuum is formed within the plurality of interconnected cells of the middle layer.

12. The sidewall assembly of claim 1, wherein at least one of an inward-facing surface of the outer layer and an outward-facing surface of the inner layer comprises un ultra-reflective infrared coating.

13. The sidewall assembly of claim 12, wherein the coating is a barium sulfate coating.

14. The sidewall assembly of claim 1, further comprising an adhesive film disposed (i) between the inner layer and the middle layer, (ii) between the middle layer and the outer layer, or (iii) between the inner layer and the middle layer and between the middle layer and the outer layer.

15. The sidewall assembly of claim 1, further comprising at least one of a bottom wall and a top wall of the substrate processing chamber.

16. A processing chamber for a substrate processing system, the processing chamber having a composite structure comprising:
a sidewall assembly enclosing a reactor volume, and
a pedestal disposed within the reactor volume, the pedestal comprising heating elements to heat a substrate supported on the pedestal,
wherein the sidewall assembly comprises:
an inner layer with an inward, reactor volume facing surface to absorb and distribute heat generated within the reactor volume,
an outer layer that encloses the inner layer to define a gap between the inner layer and the outer layer, and
a middle layer disposed around the inner layer in the gap defined between the inner layer and the outer layer, wherein the middle layer is comprised of a discontinuous heat capture structure to thermally insulate the outer layer from the inner layer.

17. The processing chamber of claim 16, wherein the inner layer is comprised of aluminum, the outer layer is comprised of one of a polymer and aluminum, and the middle layer is comprised of a honeycomb structure that defines a plurality of interconnected cells within the middle layer.

18. The processing chamber of claim 17, wherein the honeycomb structure is comprised of one or more of aramid, cellulose fiber, rayon, and modacrylic.

19. The processing chamber of claim 17, wherein the honeycomb structure is comprised of expanded metal.

20. The processing chamber of claim 17, wherein a vacuum is formed within the gap.
